(19) United States
(12) Patent Application Publication
(10) Pub. No.: US 2022/0376009 A1
(43) Pub. Date: Nov. 24, 2022

(54) SEMICONDUCTOR DEVICE AND METHOD FOR MANUFACTURING SEMICONDUCTOR DEVICE

(71) Applicant: Japan Display Inc., Tokyo (JP)

(72) Inventor: Yohei YAMAGUCHI, Tokyo (JP)

(21) Appl. No.: 17/879,829

(22) Filed: Aug. 3, 2022

Related U.S. Application Data
(63) Continuation of application No. PCT/JP2020/045475, filed on Dec. 7, 2020.

(30) Foreign Application Priority Data
Feb. 12, 2020 (JP) 2020-021378

(51) Int. Cl. H01L 27/32; H01L 51/56

(52) U.S. Cl. CPC H01L 27/3248; H01L 27/3262; H01L 51/56; H01L 2227/323; H01L 27/1225

(57) ABSTRACT

A semiconductor device includes an insulating substrate, a first semiconductor region configured of polysilicon formed on the insulating substrate, an insulating film laminated on the first semiconductor region, a contact hole formed in the insulating film and reaching the first semiconductor region, a second semiconductor region configured of an oxide semiconductor formed on the insulating film, a contact electrode configured of a conductive material and electrically connected to the first semiconductor region, where the conductive material is embedded in the contact hole. The insulating film contains a metallic element at an interface with the contact hole, where the metallic element forms the oxide semiconductor.

### CROSS-REFERENCE TO RELATED APPLICATION

The present application is Bypass Continuation of International Application No. PCT/JP2020/045475, filed on Dec. 7, 2020, which claims priority from Japanese Application No. JP2020-021378 filed on Feb. 12, 2020. The contents of these applications are hereby incorporated by reference into this application.

### BACK GROUND OF THE INVENTION

### 1. Field of the Invention

The present invention relates to a semiconductor device and a method for manufacturing the semiconductor device.

### 2. Description of the Related Art

Display devices in which a pixel circuit is configured by using a thin film transistor (TFT) on an insulating substrate have increased their practical applications. Examples of such display devices include an organic EL display device using an organic electroluminescence (EL) device and a liquid crystal display device, for example.

A typical TFT includes a semiconductor layer made of amorphous silicon and polysilicon, for example. For example, low temperature polycrystalline silicon (LTPS) formed at a low temperature is used as a semiconductor layer. Recently, TFTs including an oxide semiconductor layer, typically indium gallium zinc oxide (IGZO), as a semiconductor layer are also used in pixel circuits.

For example, a TFT using LIPS (hereinafter, LTPS-TFT) has the advantages of high reliability and high electron mobility, whereas a TFT using an oxide semiconductor (hereinafter, OS-TFT) has the advantage of low leakage current. In order to utilize such advantages of element characteristics and manufacturing process, devices such as a display device having a hybrid structure combining these TFTs have been proposed (see JP2017-173505A).

### SUMMARY OF THE INVENTION

The device including these TFTs may have a complicated manufacturing process, and is directed to reducing load and cost of the process. For example, when a signal line is connected to a source/drain portion made of an LTPS of LTPS-TFT, the surface oxide film of the LTPS is removed by hydrofluoric acid. In a case where this process is performed after the oxide semiconductor region of OS-TFT is formed, the oxide semiconductor region needs photoresist protection. However, the oxide semiconductor layer may likely disappear due to pinholes and pattern defects in the photoresist, for example.

FIG. 8 is a process flow diagram for explaining such a conventional process. In FIG. 8A, insulating films 3 to 5 and a gate electrode 6 of the LTPS-TFT are formed on an LTPS layer 2 formed on an insulating substrate 1, and an oxide semiconductor layer 7 is further formed on the surface thereof. A photoresist film 8 is formed on the surface thereof (FIG. 8B), and the insulating films 3 to 5 at openings 9 of the photoresist film 8 are removed by dry etching, for example, so as to form contact holes 10 that reach the LPTS layer 2 (FIG. 8C). After the photoresist film 8 is removed (FIG. 8C), a signal line made of metal etc. is formed in the contact holes 10 (FIG. 8D).

In this process, after the contact holes 10 are formed and before the photo resist film 8 is removed, the surface oxide film of the LIPS described above is removed by hydrofluoric acid cleaning. FIG. 9 is a schematic vertical sectional view of the oxide semiconductor layer 7 and its vicinity when performing the hydrofluoric acid cleaning. In the state of FIG. 8B, that is, at the time of forming the openings 9 by patterning the photoresist film 8, the photoresist film 8 is present up to the position indicated by a dotted line 8b, and is eroded by the process to form the subsequent contact hole 10, such as dry etching. The coverage of the photoresist film 8 can be different between the flat portion and the step portion. The photoresist film 8 can be thin or have pinholes in the step portion at the end of the oxide semiconductor layer 7. This combined with the erosion described above, the hydrofluoric acid passes through the photoresist film 8 in the step portion, and the oxide semiconductor layer is likely to disappear as described above.

One or more embodiments of the present invention have been conceived in view of the above, and an object thereof is to suitably manufacture a semiconductor device including both of an element using polysilicon and an element using an oxide semiconductor in an electronic circuit.
(1) A semiconductor device includes an insulating substrate, a first semiconductor region configured of polysilicon formed on the insulating substrate, an insulating film laminated on the first semiconductor region, a contact hole formed in the insulating film and reaching the first semiconductor region, a second semiconductor region configured of an oxide semiconductor formed on the insulating film, a contact electrode configured of a conductive material and electrically connected to the first semiconductor region, where the conductive material is embedded in the contact hole. The insulating film contains a metallic element at an interface with the contact hole, where the metallic element forming the oxide semiconductor.
(2) A method for manufacturing a semiconductor device according to another aspect of the present disclosure includes the steps of forming a first semiconductor region configured of a polysilicon film on an insulating substrate, laminating an insulating film on the first semiconductor region, forming a contact hole reaching the first semiconductor region in the insulating film, forming an oxide semiconductor film on a surface of the insulating film in which the contact hole is formed, forming an etching mask on a surface of the oxide semiconductor film, etching the oxide semiconductor film by using the etching mask to remove the oxide semiconductor film from the contact hole and form a second semiconductor region configured of the oxide semiconductor film, and embedding a conductive material in the contact hole to form a contact electrode that is electrically connected to the first semiconductor region.

### BRIEF DESCRIPTION OF THE DRAWINGS

FIG. 1 is a schematic perspective view of an organic EL display device according to an embodiment of the present invention;

FIG. 2 is a schematic plan view of the organic EL display device according to the embodiment of the present invention;

FIG. 3 is a circuit diagram of each pixel of the organic EL display device according to the embodiment of the present invention;

FIG. 4 is a schematic vertical sectional view of the organic EL display device according to the present embodiment;

FIGS. 5A to 5C are process flow diagrams illustrating features of manufacturing processes of an array substrate according to the present invention;

FIGS. 6A to 6D are process flow diagrams illustrating features of manufacturing processes of the array substrate according to the present invention;

FIG. 7 is a schematic vertical sectional view of a driving transistor DRT of the array substrate according to the present invention;

FIGS. 8A to 8D are process flow diagrams for explaining a conventional process; and

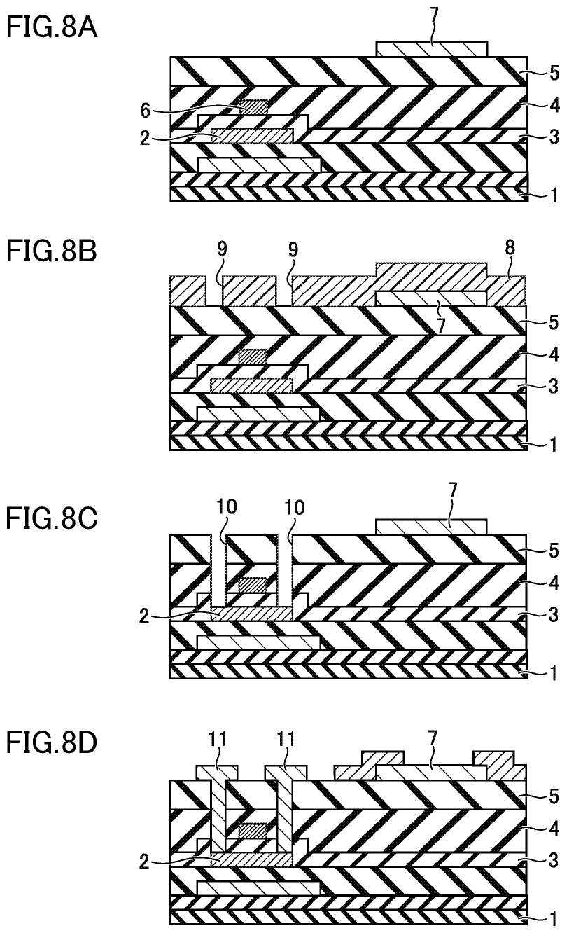

FIG. 9 is a schematic vertical sectional view of an oxide semiconductor layer and its vicinity when performing hydrofluoric acid cleaning.

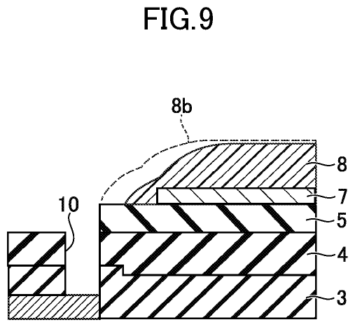

### DETAILED DESCRIPTION OF THE INVENTION

Embodiments of the present invention will be described below in detail with reference to the accompanying drawings. In this regard, the present invention is not to be limited to the embodiments described below, and can be changed as appropriate without departing from the spirit of the invention.

The accompanying drawings may schematically illustrate widths, thicknesses, shapes, or other characteristics of each part for clarity of illustration, compared to actual configurations. However, such a schematic illustration is merely an example and not intended to limit the present invention. In this specification and the drawings, some elements identical or similar to those shown previously are denoted by the same reference signs as the previously shown elements, and thus repetitive detailed descriptions of them may be omitted as appropriate.

Further, in the detailed description of the present invention, when a positional relationship between a component and another component is defined, if not otherwise stated, the words “on” and “below” suggest not only a case where the another component is disposed immediately on or below the component, but also a case where the component is disposed on or below the another component with a third component interposed therebetween.

Hereinafter, a pixel circuit in an organic EL display device will be described as an embodiment of the semiconductor device according to the present invention. The organic EL display device has a plurality of pixels arranged two-dimensionally in an image display area, and each pixel includes an organic light emitting diode (OLED) as an organic EL device.

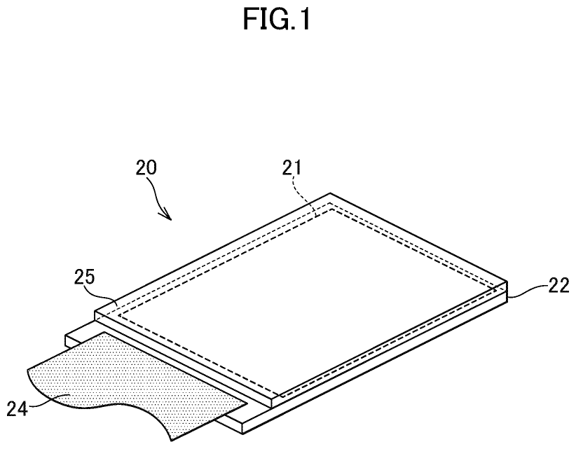

FIG. 1 is a schematic perspective view of an organic EL display device 20 according to an embodiment of the present invention. The organic EL display device 20 includes an array substrate 22 on which a display area 21 having a plurality of pixels two-dimensionally arranged are formed. The array substrate 22 corresponds to the semiconductor device in the embodiment, and the array substrate 22 is formed of a substrate (insulating substrate) made of a flexible resin film or a glass substrate, on which a laminate structure such as TFT and OLED is formed. On the array substrate 22, an OLED and a pixel circuit are formed for each pixel, and further, a driving circuit (not shown) for controlling a plurality of pixels may be formed. The signals and power for controlling the pixels are entered via a flexible print circuit (FPC) 24. The FPC 24 is adhered and electrically connected to terminals (not shown) formed on the array substrate 22. A display surface protective film 25 or a counter substrate may be provided in order to protect the display area 21.

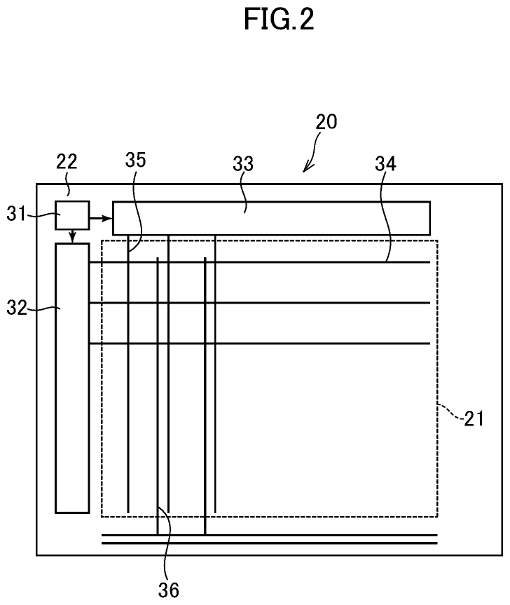

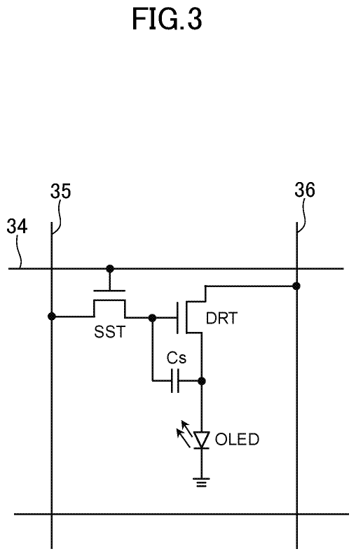

FIG. 2 is a schematic plan view of the organic EL display device 20 according to the embodiment of the present invention. FIG. 3 is a circuit diagram of each pixel of the organic EL display device 20 according to the embodiment of the present invention. The organic EL display device 20 controls light emission of an OLED provided in each pixel by a control device 31, a scanning line driving circuit 32, and a video line driving circuit 33, and displays an image.

The scanning line driving circuit 32 is connected to a scanning signal line 34 provided for each horizontal pixel array (pixel row). The video line driving circuit 33 is connected to a video signal line 35 provided for each vertical pixel array (pixel column).

The circuit of each pixel includes a pixel transistor SST, a driving transistor DRT, and a storage capacitor Cs, and is connected to the scanning signal line 34 and the video signal line 35. In response to a signal supplied from the signal lines, emission of OLED of each pixel is controlled. The pixel transistor SST and the driving transistor DRT are TFTs formed on the array substrate 22.

The gate of the pixel transistor SST is electrically connected to the scanning signal line 34. The scanning signal lines 34 of respective pixel rows are commonly connected to the gates of the SSTs arranged in the pixel rows. One of the source and drain of the SST is electrically connected to the video signal line 35, while the other is electrically connected to the gate of the driving transistor DRT. The video signal lines 35 of respective pixel columns are commonly connected to the SSTs arranged in the pixel columns. The driving transistor DRT is, for example, an n-type channel field-effect transistor, and a source is electrically connected to an anode of the OLED and a drain is electrically connected to a power supply line 36. A cathode of the OLED is fixed to a ground potential or a negative potential. The power line 36 is supplied with a potential that generates a positive voltage between a cathode potential of the OLED and the power line 36.

The scanning line driving circuit 32 sequentially selects the scanning signal lines 34 in response to a timing signal from the control device 31 and applies a voltage to turn on the pixel transistor SST to the selected scanning signal line 34.

The video line driving circuit 33 receives a video signal from the control device 31, and, in accordance with the selection of the scanning signal line 34 by the scanning line driving circuit 32, outputs a voltage corresponding to the video signal in the selected pixel row to each video signal line 35. The voltage is written to the storage capacitor Cs via the pixel transistor SST in the selected pixel row. The driving transistor DRT supplies a current corresponding to the written voltage to the OLED, and whereby the OLED of the pixel corresponding to the selected scanning signal line 34 emits light.

The pixel transistor SST and the driving transistor DRT are disclosed here as transistors forming a pixel, although a transistor having yet other functions may be included.

In FIG. 2, the scanning line driving circuit 32 and the video line driving circuit 33 are illustrated as separate blocks, but may be incorporated in one integrated circuit (IC) or divided into three or more parts. When incorporated in an IC, the scanning line driving circuit 32 and the video line driving circuit 33 may be mounted on the array substrate 22 or on the FPC shown in FIG. 1.

In the present embodiment, among the two TFTs shown in FIG. 3, the pixel transistor SST is a transistor having an oxide semiconductor layer. Specifically, the pixel transistor SST is a TFT (OS-TFT) having a channel layer made of a transparent amorphous oxide semiconductor (TAOS), and for example, IGZO is used as TAOS. As described above, the emission intensity of the OLED is determined by the current value supplied by the driving transistor DRT, and thus the gate potential of the DRT is preferably held constant throughout the emission period. As such, an OS-TFT having a small leakage current is used in a transistor connected to the gate of the DRT, i.e., SST, to prevent the leakage of charges from the gate of the DRT.

On the other hand, the driving transistor DRT of the two TFTs controls the conduction between the pixel electrode and the power supply line 36 and may be an LTPS-TFT.

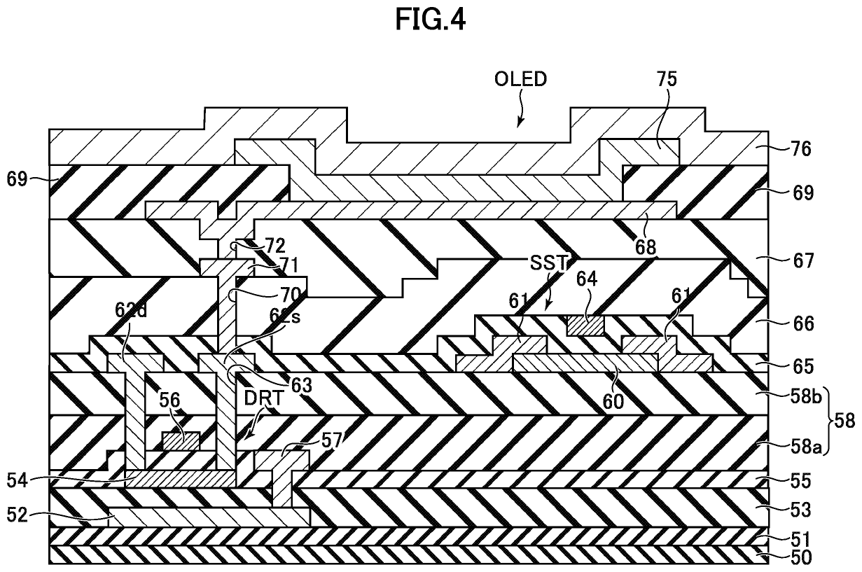

FIG. 4 is a schematic vertical sectional view of the organic EL display device 20 according to the present embodiment. Specifically, FIG. 4 is a cross-sectional view of a portion of the array substrate 22 corresponding to one pixel, and shows the pixel transistor SST, the driving transistor DRT, and the OLED. The array substrate 22 is made using a manufacturing process of a semiconductor device, and basically has a laminate structure formed in order from the lower side in FIG. 4.

The substrate 50 is made of a flexible film, such as polyimide and polyethylene terephthalate. The substrate 50 may be made of other resin or glass. An undercoat layer 51 serving as a barrier against impurities contained in the substrate 50 is provided on the upper surface of the substrate 50. The undercoat layer 51 is made of, for example, a silicon oxide film and a silicon nitride film, and may be a laminate structure of such films. For example, in the present embodiment, the undercoat layer 51 has a three-layer structure in which a silicon oxide film, a silicon nitride film, and a silicon oxide film are laminated in this order.

An additional film 52 may be provided on the undercoat layer 51 in accordance with the location of the driving transistor DRT. The additional film 52 may prevent changes in the characteristics of the transistor due to the light from the back surface of the channel, and may provide a back gate effect to the driving transistor by being formed of a conductive material and given a predetermined potential, for example. For example, the additional film 52 may be made of molybdenum (Mo), tungsten (W), or an alloy thereof (MoW).

An LTPS layer 54 serving as a semiconductor region (first semiconductor region) of the driving transistor DRT is disposed on the additional film 52 via an insulating layer 53. In the present embodiment, the LTPS layer 54 constitutes a channel region, a source region, and a drain region of the driving transistor DRT. The insulating layer 53 may be, for example, a silicon nitride film, a silicon oxide film, or a laminate film thereof.

After the LTPS layer 54 is formed, a gate insulating film 55 is formed of a silicon oxide, for example, and a metal film laminated thereon is patterned to form a gate electrode 56 of the driving transistor DRT and a signal line 57 connected to the additional film 52. For example, the metal film is formed of a three-layer structure (Ti/Al/Ti) of MoW alloy, titanium (Ti), aluminum (Al), and titanium that are laminated in this order.

An inorganic film covers the gate electrode 56, for example, to serve as an interlayer insulating film 58. In this embodiment, the interlayer insulating film 58 has a laminate structure including a silicon nitride film 58a and a silicon oxide film 58b.

A pixel transistor SST and a signal line are formed on the interlayer insulating film 58. Specifically, a TAOS layer 60 serving as a semiconductor region (second semiconductor region) of the pixel transistor SST is formed on the surface of the silicon oxide film 58b. In this embodiment, the TAOS layer 60 constitutes a channel region, a source region, and a drain region of the pixel transistor SST.

After the TAOS layer 60 is formed, a film of a conductive material is formed and patterned to form signal lines serving as source/drain electrodes (S/D electrodes) of the driving transistor DRT and the pixel transistor SST. In this regard, the conductive material is metal, for example, and a Ti/Al/Ti film is used in the present embodiment.

The S/D electrodes 61 of the pixel transistor SST overlap and electrically connect to the end surface of the TAOS layer 60. The S/D electrodes 62 (62s, 62d) of the driving transistor are connected to the LTPS layer 54 via contact holes 63 penetrating the interlayer insulating film 58 and the gate insulating film 55. Here, a portion of the LTPS layer 54 including a connection portion between the S/D electrode 62s and the LTPS layer 54 is a source region, and a portion of the LTPS layer 54 including a connection portion between the S/D electrode 62d and the LTPS layer 54 is a drain region.

After the S/D electrodes 61 and 62 are formed, a metal film laminated on the S/D electrodes 61 and 62 via the gate insulating film 65 is patterned to form a gate electrode 64 of the pixel transistor SST. That is, the pixel transistor SST is a top-gate type TFT having the gate electrode 64 on the channel region (TAOS layer 60). The gate insulating film 65 may include a recessed portion formed between the S/D electrodes 61 on the TAOS layer 60, and the gate electrode 64 may be disposed in such a recessed portion. In this case, a gap in the horizontal direction may be formed between the gate electrode 64 and the S/D electrode 61. A region of the TAOS layer 60 corresponding to the gap between below the S/D electrode 61 and below the gate electrode 64 is reduced in resistance by a process such as ion implantation through the gap.

A passivation layer 66 and a flattening layer 67 are laminated on the gate electrode 64. A pixel electrode 68, which is an anode electrode of the OLED, and a bank 69, which is formed of an insulating material and separates the pixel electrodes 68, are disposed on the surface of the flattening layer 67. The contact hole 70 reaching the S/D electrode 62s from the surface of the passivation layer 66 is provided with a vertical wire 71 for connecting the S/D electrode 62s with the pixel electrode 68, and the pixel electrode 68 is connected to the vertical wire 71 via a contact hole 72 provided in the flattening layer 67. The pixel electrode 68 may have a structure that reflects light emitted from the OLED toward the display surface, and may have a laminate structure of a transparent conductive material, such as indium tin oxide (ITO) and indium zinc oxide (IZO), and a reflective material, such as silver (Ag).

The bank 69 is disposed along the periphery of the pixel, and an area to be a light emitting surface of the OLED is an opening of the bank 69. While the bank 69 covers the end portion of the pixel electrode 68, the top surface of the pixel electrode 68 is exposed at the bottom of the opening. An organic material layer 75, which is an organic layer including a light emitting layer, is laminated on the surface of the pixel electrode 68. The bank 69 is formed of polyimide and acrylic resin, for example.

A common electrode 76 serving as a cathode electrode of the OLED is formed on the organic material layer 75. The common electrode 76 is formed of a material that transmits light emitted from the organic material layer 75. Specifically, the common electrode 76 is a semi-transparent thin film made of metal having a low work function so as to efficiently inject electrons into the organic material layer 75, and is formed of a MgAg alloy, for example.

A sealing film is disposed on the OLED, which is formed of the pixel electrode 68, the organic material layer 75, and the common electrode 76, so as to seal the upper surface of the OLED to prevent deterioration of the OLED due to moisture, although the structure above the OLED is omitted in FIG. 4.

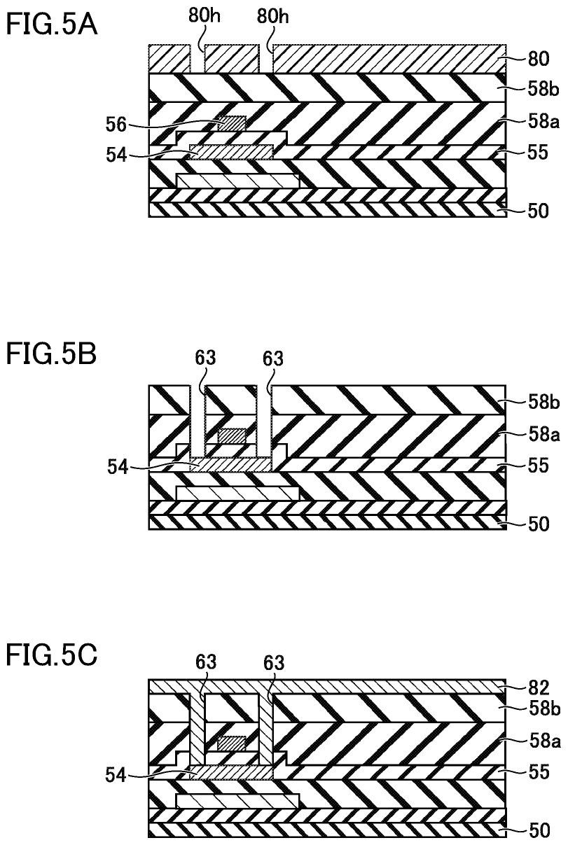

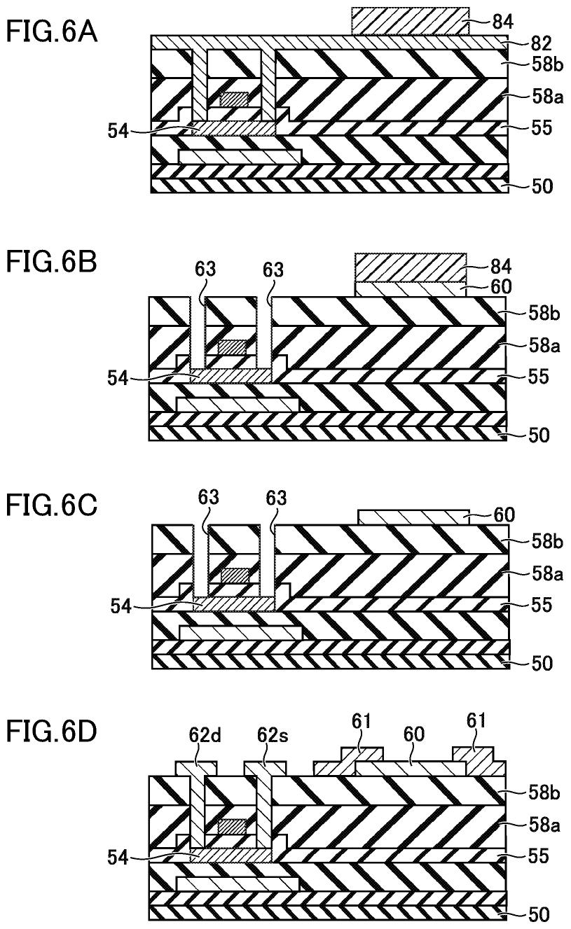

FIGS. 5 and 6 are process flow diagrams illustrating the features of the present invention in the process of manufacturing the array substrate 22 shown in FIG. 4, and showing a schematic vertical cross-sectional view of the array substrate 22 at the position corresponding to FIG. 4.

The array substrate 22 in FIG. 5A shows that the laminate structure shown in FIG. 4 in which the substrate 50 to the interlayer insulating film 58 are formed. A photoresist is applied on the surface of the interlayer insulating film 58 (silicon oxide film 58b) of the array substrate 22 and patterned by a photolithography process so as to form a photoresist film 80 having an opening 80h at a position where a contact hole 63 is formed.

The photoresist film 80 is used as an etching mask in the process such as dry etching when removing the insulating film below the opening 80h, specifically, the interlayer insulating film 58 and the gate insulating film 55, so as to form the contact hole 63 reaching the LPTS layer 54. FIG. 5B shows a state in which the contact hole 63 is formed and then the photo resist film 80 is removed.

The oxide semiconductor is applied by sputtering on the surface of the interlayer insulating film 58, on which the contact hole 63 is formed, so as to form a TAOS film 82 (FIG. 5C). For example, IGZO is used as an oxide semiconductor in this embodiment as described above. The TAOS film 82 is also formed inside the contact hole 63.

The TAOS film 82 is patterned to form a TAOS layer 60, which is a semiconductor region of the pixel transistor SST. More specifically, the photoresist applied to the surface of the TAOS film 82 is patterned by photolithography to form a photoresist film 84 at the position to form the TAOS layer 60 (FIG. 6A). The photoresist film 84 is used as a mask when performing etching process to selectively remove the TAOS layer 82 other than the masked area so as to form the TAOS layer 60 (FIG. 6B). Such etching process is, for example, wet etching using an acid as an etchant.

In the processes from FIGS. 6A to 6B, the TAOS film 82 in the contact hole 63 is also removed. Further, in these processes, the oxide film that may exist on the surface of the LTPS layer 54 is also removed in preparation for subsequently forming the S/D electrode 62 so as to expose the LTPS layer 54 on the bottom surface of the contact hole 63. The etching of the TAOS film 82 and the etching of the surface oxide film of the LTPS layer 54 may be performed using the same etchant or different etchants. For example, both the TAOS film 82 and the surface oxide film can be removed using an etchant containing hydrofluoric acid.

When the TAOS layer 60 is formed and then the surface oxide film is removed, the photoresist film 84 used as the etching mask is removed from the surface of the array substrate 22 (FIG. 6C), and a metal film is formed on the surface thereof. Such a metal film is patterned by photolithography to form S/D electrodes 61 and 62 (FIG. 6D). The S/D electrode 62 is a contact electrode to the LTPS layer 54 and is in contact with the LTPS layer 54 at the bottom surface of the contact hole 63. In this regard, the surface oxide film is removed in advance, and thus the S/D electrode 62 and the LTPS layer 54 are suitably electrically connected to each other. Subsequently, the upper structure shown in FIG. 4 is further formed, and the array substrate 22 is completed.

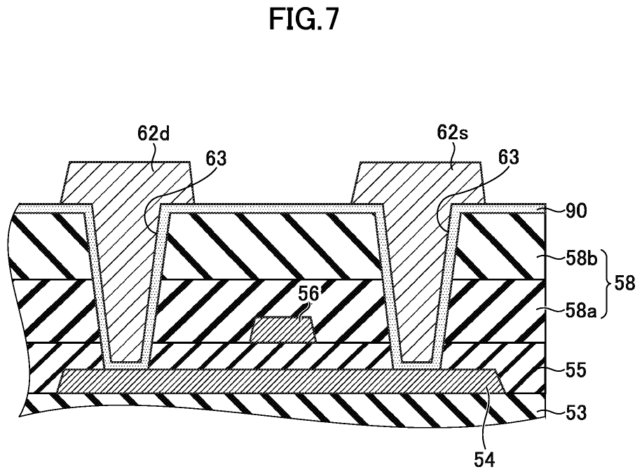

FIG. 7 is a schematic vertical sectional view of the driving transistor DRT of the array substrate 22. When the TAOS film 82 shown in FIG. 5C is formed, the constituent elements of the oxide semiconductor are implanted into the surface of the array substrate 22 to be sputtered. As a result, a layer 90 containing a metallic element to compose the oxide semiconductor is formed on the upper surface of the silicon oxide film 58b and the interface of the gate insulating film 55 and the interlayer insulating film 58 with the contact hole 63 (i.e., the surface of the insulating films 55 and 58 exposed on the side surface of the contact hole 63). As described, IGZO is used as the oxide semiconductor in the present embodiment, and correspondingly, the layer 90 containing at least one of indium, gallium, and zinc as a metallic element may be present at the interface of the insulating film with the contact hole.

While there have been described what are at present considered to be certain embodiments of the invention, it will be understood that various modifications may be made thereto, and it is intended that the appended claims cover all such modifications as fall within the true spirit and scope of the invention.

1. A semiconductor device comprising:
an insulating substrate;
a first semiconductor region configured of polysilicon formed on the insulating substrate;
an insulating film laminated on the first semiconductor region;
a contact hole formed in the insulating film and reaching the first semiconductor region;
a second semiconductor region configured of an oxide semiconductor formed on the insulating film;
a contact electrode configured of a conductive material and electrically connected to the first semiconductor region, the conductive material being embedded in the contact hole, wherein
the insulating film contains a metallic element at an interface with the contact hole, the metallic element forming the oxide semiconductor.

2. The semiconductor device according to claim 1, further comprising:
a first transistor in which a channel region is formed of the first semiconductor region; and
a top-gate type second transistor in which a channel region is formed of the second semiconductor region.

3. The semiconductor device according to claim 1, wherein
the oxide semiconductor contains indium and gallium, and
a layer containing one of indium or gallium is provided at the interface of the insulating film with the contact hole as the metallic element.

4. A method for manufacturing a semiconductor device, the method comprising steps of:
forming a first semiconductor region configured of a polysilicon film on an insulating substrate;
laminating an insulating film on the first semiconductor region;
forming a contact hole reaching the first semiconductor region in the insulating film;
forming an oxide semiconductor film on a surface of the insulating film in which the contact hole is formed;
forming an etching mask on a surface of the oxide semiconductor film;
etching the oxide semiconductor film by using the etching mask to remove the oxide semiconductor film from the contact hole and form a second semiconductor region configured of the oxide semiconductor film; and
embedding a conductive material in the contact hole to form a contact electrode that is electrically connected to the first semiconductor region.

5. The method according to claim 4, wherein
an etchant containing hydrofluoric acid is used in the etching step.

6. The method according to claim 4, wherein
the oxide semiconductor film is formed by using an oxide semiconductor material containing indium and gallium.
